(19) United States
(12) Patent Application Publication
(10) Pub. No.: US 2019/0308293 A1
(43) Pub. Date: Oct. 10, 2019

(54) METHOD OF REGULATING A SURFACE TEMPERATURE OF POLISHING PAD, AND POLISHING APPARATUS

(71) Applicant: EBARA CORPORATION, Tokyo (JP)

(72) Inventors: Keisuke Kamiki, Tokyo (JP); Mitsunori Komatsu, Tokyo (JP); Masashi Kabasawa, Tokyo (JP)

(21) Appl. No.: 16/374,108

(22) Filed: Apr. 3, 2019

(30) Foreign Application Priority Data
Apr. 6, 2018 (JP) 2018-073579

(51) Int. Cl. B24B 37/015; B24B 55/02; B24B 37/04; B24B 37/10; H01L 21/306

(52) U.S. Cl. CPC B24B 37/015; B24B 55/02; H01L 21/30625; B24B 37/10; B24B 37/042

(57) ABSTRACT

A method capable of precisely regulating a surface temperature of a polishing pad is disclosed. The method includes: determining a heating-side manipulation range by removing a dead band of a first flow-rate control valve from a range of manipulated variable for the first flow-rate control valve; setting a first manipulated variable, selected from the heating-side manipulation range, to the first flow-rate control valve; determines a cooling-side manipulation range by removing a dead band of a second flow-rate control valve from a range of manipulated variable for the second flow-rate control valve; setting a second manipulated variable, selected from the cooling-side manipulation range, to the second flow-rate control valve; and supplying a heating fluid and a cooling fluid that have passed through the flow-rate control valves to a heat exchanger to regulate a surface temperature of a polishing pad.

### CROSS REFERENCE TO RELATED APPLICATION

This document claims priority to Japanese Patent Application Number 2018-073579 filed Apr. 6, 2018, the entire contents of which are hereby incorporated by reference.

### BACKGROUND

A CMP (chemical mechanical polishing) apparatus is used in a process of polishing a surface of a wafer in manufacturing of a semiconductor device. The CMP apparatus is configured to hold and rotate the wafer with a top ring, and press the wafer against a polishing pad on a rotating polishing table to polish the surface of the wafer. During polishing, a polishing liquid (or slurry) is supplied onto the polishing pad, so that the surface of the wafer is planarized by the chemical action of the polishing liquid and the mechanical action of abrasive particles contained in the polishing liquid.

A polishing rate of the wafer depends not only on a polishing load on the wafer pressed against the polishing pad, but also on a surface temperature of the polishing pad. This is because the chemical action of the polishing liquid on the wafer depends on the temperature. Therefore, in manufacturing of a semiconductor device, it is important to maintain an optimum surface temperature of the polishing pad during polishing of the wafer in order to increase the polishing rate of the wafer and to keep the increased polishing rate constant.

From this viewpoint, a pad-temperature regulating apparatus is conventionally used to regulate a surface temperature of a polishing pad. FIG. 7 is a schematic view of a conventional pad-temperature regulating apparatus. As shown in FIG. 7, the pad-temperature regulating apparatus includes a heat exchanger 111 which is to perform heat exchange with a polishing pad 103, and a fluid supply pipe 112 coupled to the heat exchanger 111. The fluid supply pipe 112 branches into a hot-water supply pipe 115 coupled to a hot-water supply source, and a cold-water supply pipe 116 coupled to a cold-water supply source. A hot-water regulating valve 120 and a cold-water regulating valve 121 are attached to the hot-water supply pipe 115 and the cold-water supply pipe 116, respectively.

The hot-water regulating valve 120 and the cold-water regulating valve 121 are flow-rate control valves capable of regulating a flow rate of hot water and a flow rate of cold water, respectively. When the hot-water regulating valve 120 and the cold-water regulating valve 121 change the flow rate of the hot water and the flow rate of the cold water, the temperature of the heat exchanger 111 changes. The heat exchange is performed between the heat exchanger 11 and the polishing pad 103, and as a result, the surface temperature of the polishing pad 103 changes.

Operations of the hot-water regulating valve 120 and the cold-water regulating valve 121 are controlled by a valve controller 130. More specifically, the valve controller 130 determines manipulated variables for the hot-water regulating valve 120 and the cold-water regulating valve 121 for minimizing a difference between the surface temperature of the polishing pad 103 and a target temperature, and sends the determined manipulated variables to the hot-water regulating valve 120 and the cold-water regulating valve 121, respectively. The hot-water regulating valve 120 and the cold-water regulating valve 121 operate in accordance with the manipulated variables to thereby regulate the flow rate of the hot water and the flow rate of the cold water.

However, the hot-water regulating valve 120 and the cold-water regulating valve 121 have dead bands where the flow rates do not change in response to the change in the manipulated variables. For example, as shown in FIG. 8, the manipulated variable for the hot-water regulating valve 120 can change within the range of 0% to 100%, but the flow rate does not change when the manipulated variable for the hot-water regulating valve 120 changes in a range of 0% to 20% and in a range of 80% to 100%. In an example shown in FIG. 9, the manipulated variable for the cold-water regulating valve 121 can change within the range of 0% to 100%, but the flow rate does not change when the manipulated variable for the cold-water regulating valve 121 changes in a range of 0% to 30% and in a range of 50% to 100%. The presence of such dead bands prevent the surface temperature of the polishing pad 103 from reaching the target temperature.

Possible causes of the dead bands are the structures of the hot-water regulating valve 120 and the cold-water regulating valve 121. FIG. 10 is a schematic diagram of a flow-rate control valve used for the hot-water regulating valve 120 and the cold-water regulating valve 121. The flow-rate control valve has a housing 140, a partition wall 155 having an orifice 150, a conical valve element 160 for closing the orifice 150, and an actuator 165 for moving the valve element 160. The actuator 165 has a pressure chamber 170 in which compressed air is supplied, and a diaphragm 171 facing the pressure chamber 170. The valve element 160 is fixed to one end of a piston rod 172, and the other end of the piston rod 172 is fixed to the diaphragm 171. The diaphragm 171 deforms according to pressure of the compressed air in the pressure chamber 170, and the diaphragm 171 pushes the valve element 160 through the piston rod 172 in a direction away from the orifice 150. The pressure of the compressed air in the pressure chamber 170 is regulated by a pressure regulator 175. The partition wall 155 and the valve element 160 are located in the housing 140. The interior of the housing 140 is divided by the partition wall 155 into an inflow-side chamber 156 and an outflow-side chamber 157. The housing 140 has a fluid inlet 158 communicating with the inflow-side chamber 156 and a fluid outlet 159 communicating with the outflow-side chamber 157.

The actuator 165 can change the flow rate of the liquid by changing a gap between the valve element 160 and the orifice 150. The manipulated variable for the flow-rate control valve corresponds to a magnitude of a force applied by the actuator 165 to the valve element 160 in a direction in which the valve element 160 is opened. Specifically as the manipulated variable for the flow-rate control valve increases, the force applied to the valve element 160 by the actuator 165 increases, and the opening degree of the valve element 160 increases.

When the valve element 160 closes the orifice 150, both a primary pressure P1 of a liquid and a secondary pressure P2 of a liquid are applied to the valve element 160 (P1>P2). At this time, the liquid pushes the valve element 160 in a direction in which the valve element 160 closes. Therefore, the valve element 160 does not open until the force applied to the valve element 160 by the actuator 165 increases to some extent. As a result, even if the manipulated variable for the flow-rate control valve changes from 0% to some extent, the flow rate does not change. On the other hand, as shown in FIG. 11, when the valve element 160 approaches full opening, the flow rate of the liquid reaches the maximum value before the valve element 160 is fully opened. Due to such mechanisms, the flow-rate control valve has a lower-side dead band and a higher-side dead band where the flow rate does not change even when the manipulated variable is changed.

### SUMMARY OF THE INVENTION

According to an embodiment, there is provided a method capable of precisely regulating a surface temperature of a polishing pad by eliminating an influence of dead bands of flow-rate control valves that regulate flow rates of a heating fluid and a cooling fluid. According to another embodiment, there is provided a polishing apparatus for polishing a substrate, such as a wafer, while regulating a surface temperature of a polishing pad.

Embodiments, which will be described below, relate to a method of regulating a surface temperature of a polishing pad for use in polishing of a substrate, such as a wafer. The below-described embodiments also relate to a polishing apparatus for polishing a substrate, such as a wafer, while regulating a surface temperature of a polishing pad.

In an embodiment, there is provided a method comprising: determining a heating-side manipulation range by removing a dead band of a first flow-rate control valve from a range of manipulated variable for the first flow-rate control valve; setting a first manipulated variable, selected from the heating-side manipulation range, to the first flow-rate control valve to cause the first flow-rate control valve to operate according to the selected first manipulated variable; determines a cooling-side manipulation range by removing a dead band of a second flow-rate control valve from a range of manipulated variable for the second flow-rate control valve; setting a second manipulated variable, selected from the cooling-side manipulation range, to the second flow-rate control valve to cause the second flow-rate control valve to operate according to the selected second manipulated variable; and supplying a heating fluid that has passed through the first flow-rate control valve and a cooling fluid that has passed through the second flow-rate control valve to a heat exchanger disposed over a polishing pad to regulate a surface temperature of the polishing pad.

In an embodiment, a sum of the first manipulated variable, selected from the heating-side manipulation range, and the second manipulated variable, selected from the cooling-side manipulation range, is 100% where each of the heating-side manipulation range and the cooling-side manipulation range is expressed as numerical values from 0% to 100%.

In an embodiment, the dead band of the first flow-rate control valve includes a lower-side dead band located in a lower side of the range of manipulated variable for the first flow-rate control valve, and a higher-side dead band located in a higher side of the range of manipulated variable for the first flow-rate control valve.

In an embodiment, a lower limit value of the heating-side manipulation range is equal to or larger than an upper limit value of the lower-side dead band of the first flow-rate control valve, and an upper limit value of the heating-side manipulation range is equal to or smaller than a lower limit value of the higher-side dead band of the first flow-rate control valve.

In an embodiment, the dead band of the second flow-rate control valve includes a lower-side dead band located in a lower side of the range of manipulated variable for the second flow-rate control valve, and a higher-side dead band located in a higher side of the range of manipulated variable for the second flow-rate control valve.

In an embodiment, a lower limit value of the cooling-side manipulation range is equal to or larger than an upper limit value of the lower-side dead band of the second flow-rate control valve, and an upper limit value of the cooling-side manipulation range is equal to or smaller than a lower limit value of the higher-side dead band of the second flow-rate control valve.

In an embodiment, there is provided a polishing apparatus comprising: a polishing table for supporting a polishing pad; a polishing head configured to press a substrate against a surface of the polishing pad to polish the substrate; an heat exchanger provided over the polishing pad; a heating-fluid supply line and a cooling-fluid supply line coupled to the heat exchanger; a first flow-rate control valve attached to the heating-fluid supply line; a second flow-rate control valve attached to the cooling-fluid supply line; and a valve controller coupled to the first flow-rate control valve and the second flow-rate control valve, the valve controller comprising instructions configured to: determine a heating-side manipulation range by removing a dead band of the first flow-rate control valve from a range of manipulated variable for the first flow-rate control valve; set a first manipulated variable, selected from the heating-side manipulation range, to the first flow-rate control valve to cause the first flow-rate control valve to operate according to the selected first manipulated variable; determine a cooling-side manipulation range by removing a dead band of the second flow-rate control valve from a range of manipulated variable for the second flow-rate control valve; and set a second manipulated variable, selected from the cooling-side manipulation range, to the second flow-rate control valve to cause the second flow-rate control valve to operate according to the selected second manipulated variable.

In an embodiment, a sum of the first manipulated variable, selected from the heating-side manipulation range, and the second manipulated variable, selected from the cooling-side manipulation range, is 100% where each of the heating-side manipulation range and the cooling-side manipulation range is expressed as numerical values from 0% to 100%.

In an embodiment, the dead band of the first flow-rate control valve includes a lower-side dead band located in a lower side of the range of manipulated variable for the first flow-rate control valve, and a higher-side dead band located in a higher side of the range of manipulated variable for the first flow-rate control valve.

In an embodiment, a lower limit value of the heating-side manipulation range is equal to or larger than an upper limit value of the lower-side dead band of the first flow-rate control valve, and an upper limit value of the heating-side manipulation range is equal to or smaller than a lower limit value of the higher-side dead band of the first flow-rate control valve.

In an embodiment, the dead band of the second flow-rate control valve includes a lower-side dead band located in a lower side of the range of manipulated variable for the second flow-rate control valve, and a higher-side dead band located in a higher side of the range of manipulated variable for the second flow-rate control valve.

In an embodiment, a lower limit value of the cooling-side manipulation range is equal to or larger than an upper limit value of the lower-side dead band of the second flow-rate control valve, and an upper limit value of the cooling-side manipulation range is equal to or smaller than a lower limit value of the higher-side dead band of the second flow-rate control valve.

According to the above-described embodiments, the manipulated variable for the first flow-rate control valve and the manipulated variable for the second flow-rate control valve are respectively selected from the heating-side range and the cooling-side range from which dead bands have been removed. Therefore, the first flow-rate control valve and the second flow-rate control valve can precisely regulate the flow rates of the heating fluid and the cooling fluid. While the polishing pad is maintained at an optimum surface temperature, a substrate, such as the wafer, is polished on the polishing pad.

### BRIEF DESCRIPTION OF THE DRAWINGS

FIG. 1 is a schematic view showing one embodiment of a polishing apparatus;

FIG. 2 is a diagram for explaining a process of removing dead zones from a range of manipulated variable for a first flow-rate control valve;

FIG. 3 is a diagram for explaining a process of removing dead zones from a range of manipulated variable for a second flow-rate control valve;

FIG. 4 is a horizontal cross-sectional view showing an embodiment of a heat exchanger;

FIG. 5 is a plan view showing a positional relationship between the heat exchanger and a polishing head on a polishing pad;

FIG. 6 is a schematic view showing an example of a configuration of a valve controller;

FIG. 7 is a schematic diagram showing a conventional pad-temperature regulating apparatus;

FIG. 8 is a view for explaining dead zones of a hot-water control valve;

FIG. 9 is a view for explaining dead zones of a cold-water control valve;

FIG. 10 is a schematic view of a flow control valve used for the hot-water control valve and the cold-water control valve; and

FIG. 11 is a schematic view showing a state in which a valve element shown in FIG. 10 is approaching full opening.

### DESCRIPTION OF EMBODIMENTS

Embodiments will now be described with reference to the drawings.

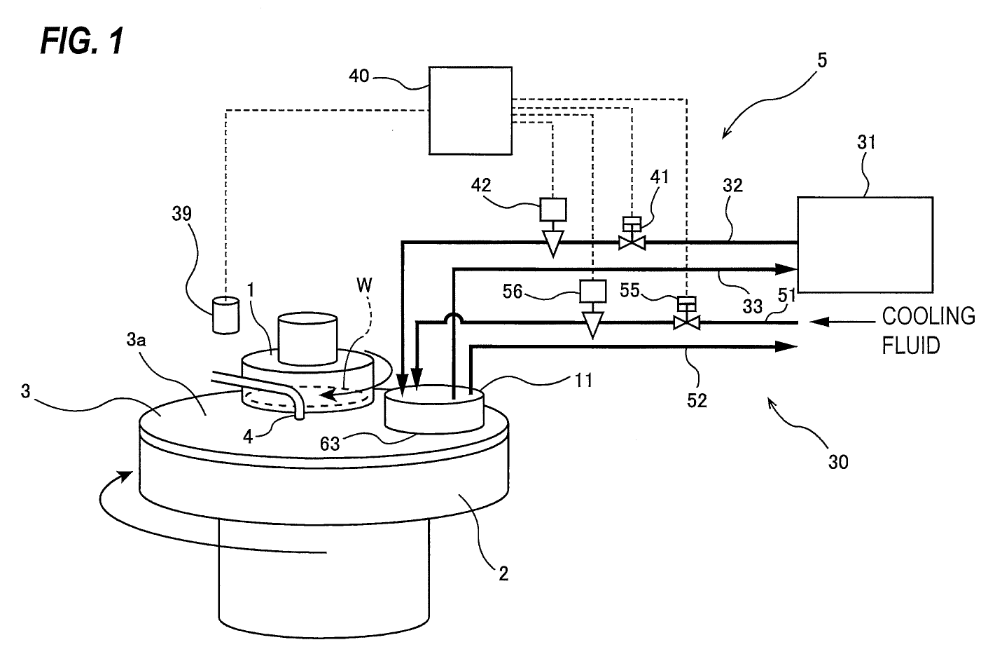

FIG. 1 is a schematic view showing an embodiment of a polishing apparatus. As shown in FIG. 1, the polishing apparatus includes a polishing head 1 for holding and rotating a wafer W which is an example of a substrate, a polishing table 2 that supports a polishing pad 3, a polishing-liquid supply nozzle 4 for supplying a polishing liquid (e.g. a slurry) onto a surface of the polishing pad 3, and a pad-temperature regulation system 5 for regulating a surface temperature of the polishing pad 3. The surface (upper surface) 3a of the polishing pad 3 provides a polishing surface for polishing the wafer W.

The polishing head 1 is vertically movable, and is rotatable about its axis in a direction indicated by arrow. The wafer W is held on a lower surface of the polishing head 1 by, for example, vacuum suction. A motor (not shown) is coupled to the polishing table 2, so that the polishing table 2 can rotate in a direction indicated by arrow. As shown in FIG. 1, the polishing head 1 and the polishing table 2 rotate in the same direction. The polishing pad 3 is attached to the upper surface of the polishing table 2.

Polishing of the wafer W is performed in the following manner. The wafer W, to be polished, is held by the polishing head 1, and is then rotated by the polishing head 1. The polishing pad 3 is rotated together with the polishing table 2. While the wafer W and the polishing pad 3 are rotating, the polishing liquid is supplied from the polishing-liquid supply nozzle 4 onto the surface 3a of the polishing pad 3, and the surface of the wafer W is then pressed by the polishing head 1 against the surface 3a, i.e. the polishing surface, of the polishing pad 3. The surface of the wafer W is polished by the sliding contact with the polishing pad 3 in the presence of the polishing liquid. The surface of the wafer W is planarized by the chemical action of the polishing liquid and the mechanical action of abrasive grains contained in the polishing liquid.

The pad-temperature regulation system 5 includes a heat exchanger 11 having flow passages formed therein through which fluids flow to regulate the surface temperature of the polishing pad 3. The pad-temperature regulation system 5 further includes a fluid supply system 30 for supplying a heating fluid having a regulated temperature and a cooling fluid having a regulated temperature into the heat exchanger 11. The heat exchanger 11 has a pad contact surface 63 which can contact the surface 3a of the polishing pad 3. The heat exchanger 11 is located above the polishing table 2 and is disposed on the surface 3a of the polishing pad 3.

The fluid supply system 30 includes a heating-fluid supply tank 31 as a heating-fluid supply source for holding the heating fluid having a regulated temperature therein, and a heating-fluid supply line 32 and a heating-fluid return line 33, each coupling the heating-fluid supply tank 31 to the heat exchanger 11. One ends of the heating-fluid supply line 32 and the heating-fluid return line 33 are coupled to the heating-fluid supply tank 31, and the other ends are coupled to the heat exchanger 11.

The heating fluid having a regulated temperature is supplied from the heating-fluid supply tank 31 to the heat exchanger 11 through the heating-fluid supply line 32, flows in the heat exchanger 11, and is returned from the heat exchanger 11 to the heating-fluid supply tank 31 through the heating-fluid return line 33. In this manner, the heating fluid circulates between the heating-fluid supply tank 31 and the heat exchanger 11. The heating-fluid supply tank 31 has a heater (not shown in the drawings), so that the heating fluid is heated by the heater to have a predetermined temperature.

A first on-off valve 41 and a first flow-rate control valve 42 are attached to the heating-fluid supply line 32. The first flow-rate control valve 42 is located between the heat exchanger 11 and the first on-off valve 41. The first on-off valve 41 is a valve not having a flow rate regulating function, whereas the first flow-rate control valve 42 is a valve having a flow rate regulating function. As the first flow-rate control valve 42, an actuator-driven valve, such as a mass flow controller, is used. An example of the configuration of the first flow-rate control valve 42 is the same as the flow-rate control valve described with reference to FIG. 10.

The fluid supply system 30 further includes a cooling-fluid supply line 51 and a cooling-fluid discharge line 52, both coupled to the heat exchanger 11. The cooling-fluid supply line 51 is coupled to a cooling-fluid supply source (e.g. a cold water supply source) provided in a factory in which the polishing apparatus is installed. The cooling fluid is supplied to the heat exchanger 11 through the cooling-fluid supply line 51, flows in the heat exchanger 11, and is drained from the heat exchanger 11 through the cooling-fluid discharge line 52. In one embodiment, the cooling fluid that has flowed through the heat exchanger 11 may be returned to the cooling-fluid supply source through the cooling-fluid discharge line 52.

A second on-off valve 55 and a second flow-rate control valve 56 are attached to the cooling-fluid supply line 51. The second flow-rate control valve 56 is located between the heat exchanger 11 and the second on-off valve 55. The second on-off valve 55 is a valve not having a flow rate regulating function, whereas the second flow-rate control valve 56 is a valve having a flow rate regulating function. As the second flow-rate control valve 56, an actuator-driven valve, such as a mass flow controller, is used. An example of the configuration of the second flow-rate control valve 56 is the same as the flow-rate control valve described with reference to FIG. 10.

The pad-temperature regulation system 5 further includes a pad-temperature measuring device 39 for measuring a surface temperature of the polishing pad 3 (which may hereinafter be referred to as pad surface temperature), and a valve controller 40 for operating the first flow-rate control valve 42 and the second flow-rate control valve 56 based on the pad surface temperature measured by the pad-temperature measuring device 39. The first on-off valve 41 and the second on-off valve 55 are usually open. The pad-temperature measuring device 39 is disposed above the surface 3a of the polishing pad 3, and is configured to measure the surface temperature of the polishing pad 3 in a non-contact manner. The pad-temperature measuring device 39 is coupled to the valve controller 40.

The valve controller 40 is configured to determine a manipulated variable for the first flow-rate control valve 42 and a manipulated variable for the second flow-rate control valve 56 which are necessary for eliminating a difference between a preset target temperature and the surface temperature of the polishing pad 3. The manipulated variable for the first flow-rate control valve 42 and the manipulated variable for the second flow-rate control valve 56 are transmitted to the first flow-rate control valve 42 and the second flow-rate control valve 56, respectively.

The manipulated variable for the first flow-rate control valve 42 and the manipulated variable for the second flow-rate control valve 56 are, in other words, valve opening degrees. However, in the first flow-rate control valve 42, there is a dead band in which the flow rate does not change when the manipulated variable is changed. Similarly, in the second flow-rate control valve 56, there is a dead band in which the flow rate does not change when the manipulated variable is changed. If the manipulated variable, calculated by the valve controller 40, is within the dead band, the first flow-rate control valve 42 and/or the second flow-rate control valve 56 cannot change the flow rate. As a result, the heat exchanger 11 cannot change the surface temperature of the polishing pad 3. Thus, in the present embodiment, the influence of the dead band is eliminated as follows.

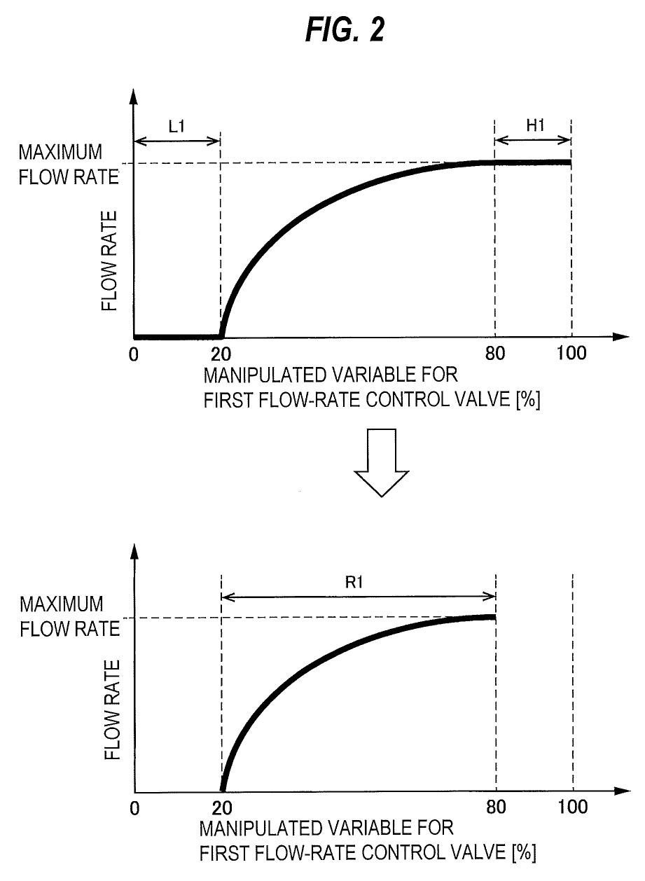

The valve controller 40 removes the dead band of the first flow-rate control valve 42 from a range of manipulated variable for the first flow-rate control valve 42 to thereby determine a heating-side manipulation range that does not include the dead band. FIG. 2 is a diagram for explaining a process of removing the dead band from the range of manipulated variable for the first flow-rate control valve 42. In a graph of FIG. 2, vertical axis represents flow rate of the heating fluid, and horizontal axis represents manipulated variable for the first flow-rate control valve 42. The range of manipulated variable for the first flow-rate control valve 42 is represented by numerical values from 0% to 100%.

In the example shown in FIG. 2, the dead band of the first flow-rate control valve 42 includes a lower-side dead band L and a higher-side dead band H1. The lower-side dead band L1 is a range located in a lower side of the range of manipulated variable (0 to 100%) for the first flow-rate control valve 42. In the example shown in FIG. 2, the lower-side dead band L1 is a range of 0% to 20% including 0% which is the lower limit value of the range of manipulated variable for the first flow-rate control valve 42. The higher-side dead band H1 is a range located in a higher side of the range of manipulated variable (0 to 100%) for the first flow-rate control valve 42. In the example shown in FIG. 2, the higher-side dead band H1 is a range of 80% to 100% including 100% which is the upper limit value of the range of manipulated variable for the first flow-rate control valve 42.

The specific range (0% to 20%, 80% to 100%) of each of the lower-side dead band L1 and the higher-side dead band H1 can be determined in advance by actual operations or experiments. The dead band of the first flow-rate control valve 42 may be either the lower-side dead band L1 or the higher-side dead band H1.

The valve controller 40 removes the lower-side dead band L1 (0% to 20%) and the higher-side dead band H1 (80% to 100%) from the range (0 to 100%) of the manipulated variable for the first flow-rate control valve 42, thereby determining the heating-side manipulation range R1 shown in FIG. 2. The lower limit value of the heating-side manipulation range R1 is equal to or larger than the upper limit value of the lower-side dead band L of the first flow-rate control valve 42, i.e., the lower limit value of the heating-side manipulation range R1 is 20% or more. In the example shown in FIG. 2, the lower limit value of the heating-side manipulation range R1 is 20% which is the same as the upper limit value of the lower-side dead band L1 of the first flow-rate control valve 42. In one embodiment, the lower limit value of the heating-side manipulation range R1 may be larger than the upper limit value of the lower-side dead band L1 of the first flow-rate control valve 42. The upper limit value of the heating-side manipulation range R1 is equal to or smaller than the lower limit value of the higher-side dead band H1 of the first flow-rate control valve 42, i.e., 80% or less. In the example shown in FIG. 2, the upper limit value of the heating-side manipulation range R1 is 80% which is the same as the lower limit value of the higher-side dead band H1 of the first flow-rate control valve 42. In one embodiment, the upper limit value of the heating-side manipulation range R1 may be smaller than the lower limit value of the higher-side dead band H1 of the first flow-rate control valve 42.

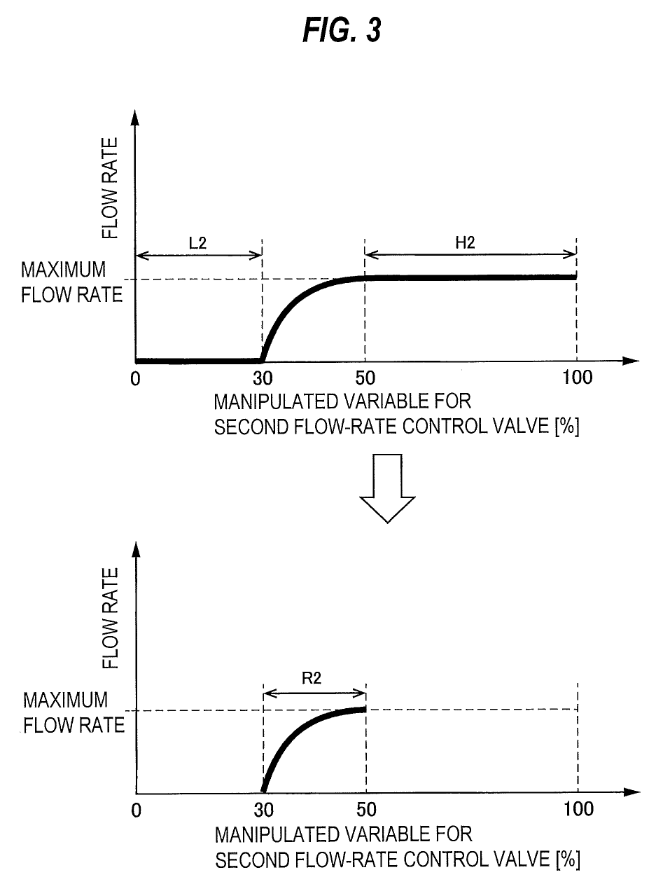

Similarly, the valve controller 40 removes the dead band of the second flow-rate control valve 56 from the range of manipulated variable for the second flow-rate control valve 56 to thereby determine a cooling-side manipulation range that does not include the dead band. FIG. 3 is a diagram for explaining a process of removing the dead band from the range of manipulated variable for the second flow-rate control valve 56. In a graph of FIG. 3, vertical axis represents flow rate of the cooling fluid, and horizontal axis represents manipulated variable for the second flow-rate control valve 56. The range of manipulated variable for the second flow-rate control valve 56 is represented by numerical values from 0% to 100%.

In the example shown in FIG. 3, the dead band of the second flow-rate control valve 56 includes a lower-side dead band L2 and a higher-side dead band H2. The lower-side dead band L2 is a range located in a lower side of the range of manipulated variable (0 to 100%) for the second flow-rate control valve 56. In the example shown in FIG. 3, the lower-side dead band L2 is a range of 0% to 30% including 0% which is the lower limit value of the range of manipulated variable for the second flow-rate control valve 56. The higher-side dead band H2 is a range located in a higher side of the range of manipulated variable (0 to 100%) for the second flow-rate control valve 56. In the example shown in FIG. 3, the higher-side dead band H2 is a range of 50% to 100% including 100% which is the upper limit value of the range of manipulated variable for the second flow-rate control valve 56. The specific range (0% to 30%, 50% to 100%) of each of the lower-side dead band L2 and the higher-side dead band H2 can be determined in advance by actual operations or experiments. The dead band of the second flow-rate control valve 56 may be either the lower-side dead band L2 or the higher-side dead band H2.

The valve controller 40 removes the lower-side dead band L2 (0% to 30%) and the higher-side dead band 112 (50% to 100%) from the range of manipulated variable (0 to 100%) for the second flow-rate control valve 56, thereby determining the cooling-side manipulation range R2 shown in FIG. 3. The lower limit value of the cooling-side manipulation range R2 is equal to or larger than the upper limit value of the lower-side dead band L2 of the second flow-rate control valve 56, i.e., the lower limit value of the cooling-side manipulation range R2 is 30% or more. In the example shown in FIG. 3, the lower limit value of the cooling-side manipulation range R2 is 30% which is the same as the upper limit value of the lower-side dead band L2 of the second flow-rate control valve 56. In one embodiment, the lower limit value of the cooling-side manipulation range R2 may be larger than the upper limit value of the lower-side dead band L2 of the second flow-rate control valve 56. The upper limit value of the cooling-side manipulation range R2 is equal to or smaller than the lower limit value of the higher-side dead band H2 of the second flow-rate control valve 56, i.e., the upper limit value of the cooling-side manipulation range R2 is 50% or less. In the example shown in FIG. 3, the upper limit value of the cooling-side manipulation range R2 is 50% which is the same as the lower limit value of the higher-side dead band H2 of the second flow-rate control valve 56. In one embodiment, the upper limit value of the cooling-side manipulation range R2 may be smaller than the lower limit value of the higher-side dead band H2 of the second flow-rate control valve 56.

The valve controller 40 selects, from the heating-side manipulation range R1 and the cooling-side manipulation range R2, a manipulated variable for the first flow-rate control valve 42 and a manipulated variable for the second flow-rate control valve 56, respectively, which can minimize a difference between a preset target temperature and the surface temperature of the polishing pad 3. Then, the valve controller 40 transmits the manipulated variable, selected from the heating-side manipulation range R1, to the first flow-rate control valve 42, and causes the first flow-rate control valve 42 to operate according to the selected manipulated variable. Similarly, the valve controller 40 transmits the manipulated variable, selected from the cooling-side manipulation range R2, to the second flow-rate control valve 56, and causes the second flow-rate control valve 56 to operate according to the selected manipulated variable.

The heating fluid, with its flow rate regulated by the first flow-rate control valve 42, is supplied to the heat exchanger 11 through the heating-fluid supply line 32, and the cooling fluid, with its flow rate regulated by the second flow-rate control valve 56, is supplied to the heat exchanger 11 through the cooling-fluid supply line 51. The heating fluid and the cooling fluid simultaneously flow in the heat exchanger 11. The temperature of the heat exchanger 11 varies depending on the temperatures of the heating fluid and the cooling fluid.

As described above, the manipulated variable for the first flow-rate control valve 42 and the manipulated variable for the second flow-rate control valve 56 are selected from the heating-side manipulation range R1 and the cooling-side manipulation range R2, respectively, which do not include the dead bands. Therefore, the first flow-rate control valve 42 and the second flow-rate control valve 56 can precisely regulate the flow rates of the heating fluid and the cooling fluid. While the polishing pad 3 is maintained at an optimum surface temperature, the wafer W is polished on the polishing pad 3.

When each of the heating-side manipulation range R1 and the cooling-side manipulation range R2 is expressed as numerical values from 0% to 100%, the sum of a manipulated variable selected from the heating-side manipulation range R1 and a manipulated variable selected from the cooling-side manipulation range R2 is 100%. Since the sum of the flow rate of the heating fluid and the flow rate of the cooling fluid is kept constant, hunting of the surface temperature of the polishing pad 3 is prevented. In one embodiment, the valve controller 40 may determine a manipulated variable for the second flow-rate control valve 56 by subtracting, from 100%, a manipulated variable for the first flow-rate control valve 42 selected from the heating-side manipulation range R1. In one embodiment, the valve controller 40 may determine a manipulated variable for the first flow-rate control valve 42 by subtracting, from 100%, a manipulated variable for the second flow-rate control valve 56 selected from the cooling-side manipulation range R2.

Hot water may be used as the heating fluid supplied to the heat exchanger 11. The hot water is heated by the heater of the heating-fluid supply tank 31 to have a temperature of about, for example, 80° C. In order to increase the surface temperature of the polishing pad 3 more quickly, silicone oil may be used as the heating fluid. When silicone oil is used as the heating fluid, the silicone oil is heated by the heater of the heating fluid supply tank 31 to have a temperature of 100° C. or more (e.g., about 120° C.). Cold water or silicone oil may be used as the cooling fluid supplied to the heat exchanger 11. In the case of using silicone oil as the cooling fluid, a chiller, which is a cooling-fluid supply source, may be coupled to the cooling fluid supply line 51 so as to cool the silicone oil to 0° C. or less, so that the heat exchanger 11 can quickly cool the polishing pad 3.

The heating-fluid supply line 32 and the cooling-fluid supply line 51 are completely independent pipes. Therefore, the heating fluid and the cooling fluid are supplied to the heat exchanger 11 without being mixed with each other. The heating-fluid return line 33 and the cooling-fluid discharge line 52 are also completely independent pipes. Accordingly, the heating fluid is returned to the heating fluid supply tank 31 without being mixed with the cooling fluid, and the cooling fluid is drained or is returned to the cooling fluid supply source without being mixed with the heating fluid.

Next, an embodiment of the heat exchanger 11 will be described. FIG. 4 is a horizontal cross-sectional view showing an embodiment of the heat exchanger 11. The heat exchanger 11 is a pad contact member having a heating flow passage 61 and a cooling flow passage 62 formed therein. The heat exchanger 11 includes the heating flow passage 61 through which the heating fluid flows, the cooling flow passage 62 through which the cooling fluid flows, and the pad contact surface 63 capable of contacting the surface 3a of the polishing pad 3. In this embodiment, the pad contact surface 63 has a circular shape. In one embodiment, the pad contact surface 63 may have a polygonal shape such as a quadrangle, a pentagon, or the like. A material having excellent thermal conductivity, abrasion resistance, corrosion resistance, such as SiC or alumina, can be used as a material for forming the heating flow passage 61, the cooling flow passage 62, and the pad contact surface 63.

The heating flow passage 61 and the cooling flow passage 62 are arranged side by side, and extend in a spiral shape. Further, the heating flow passage 61 and the cooling flow passage 62 have a shape of point symmetry, and have the same length. The heating flow passage 61 and the cooling flow passage 62 are completely separated, so that the heating fluid and the cooling fluid are not mixed in the heat exchanger 11.

As shown in FIG. 4, the heating flow passage 61 and the cooling flow passage 62 are each basically composed of a plurality of arc-shaped flow passages 64 having a constant curvature, and a plurality of oblique flow passages 65 coupling the arc-shaped flow passages 64. Two adjacent arc-shaped flow passages 64 are coupled to each other by each oblique flow passage 65. Such a construction makes it possible to locate the outermost portions of the heating flow passage 61 and the cooling flow passage 62 at an outermost portion of the heat exchanger 11. Specifically, most of the pad contact surface 63, i.e. the lower surface, of the heat exchanger 11 lies under the heating flow passage 61 and the cooling flow passage 62. Therefore, the heating liquid and the cooling liquid can quickly heat and cool the surface 3a of the polishing pad 3.

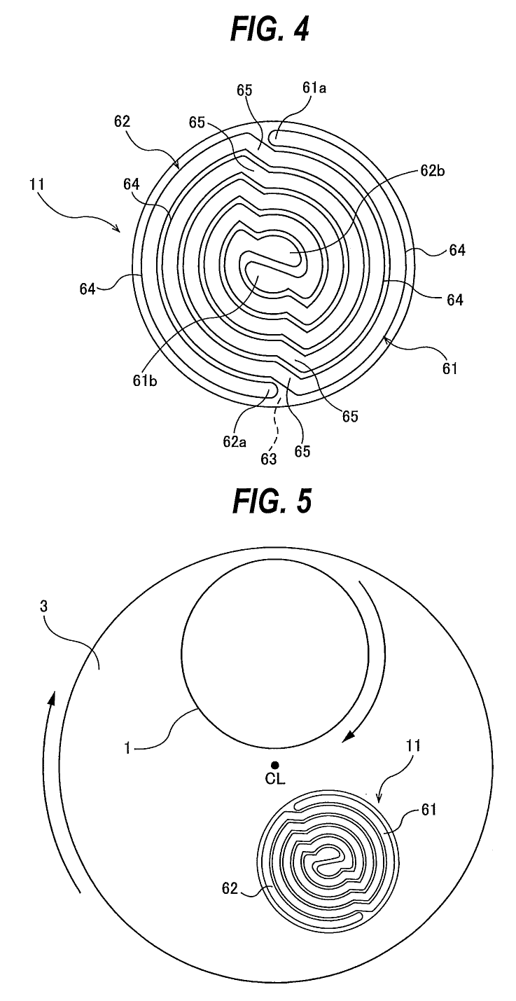

FIG. 5 is a plan view showing a positional relationship between the heat exchanger 11 and the polishing head 1 on the polishing pad 3. The heat exchanger 11 has a circular shape when viewed from above, and has a diameter which is smaller than the diameter of the polishing head 1. A distance from the center CL of the polishing pad 3 to the center of the heat exchanger 11 is equal to a distance from the center CL of the polishing pad 3 to the center of the polishing head 1. Since the heating flow passage 61 and the cooling flow passage 62 are adjacent to each other, the heating flow passage 61 and the cooling flow passage 62 are arranged along the circumferential direction of the polishing pad 3. While the polishing table 2 and the polishing pad 3 are rotating, the polishing pad 3 in contact with the heat exchanger 11 performs the heat exchange with both of the heating fluid and the cooling fluid.

Both the heating flow passage 61 and the cooling flow passage 62 are located over the entirety of the pad contact surface 63. This arrangement can enable the heat exchanger 11 to regulate the surface temperature of the polishing pad 3 by both the heating fluid and the cooling fluid with the entirety of the pad contact surface 63. Therefore, the heat exchanger 11 can provide a uniform distribution of the surface temperature of the polishing pad 3. Furthermore, the polishing apparatus having the above-discussed heat exchanger 11 can polish a substrate, such as a wafer, to provide a uniform polishing profile.

In order to maintain the pad surface temperature at a predetermined target temperature, the heat exchanger 11 is placed in contact with the surface (i.e. the polishing surface 3a) of the polishing pad 3 during polishing of the wafer W. In this specification, the manner of contact of the heat exchanger 11 with the surface of the polishing pad 3 includes not only direct contact of the heat exchanger 11 with the surface of the polishing pad 3, but also contact of the heat exchanger 11 with the surface of the polishing pad 3 in the presence of a polishing liquid (or slurry) between the heat exchanger 11 and the surface of the polishing pad 3. In either case, the heat exchange occurs between the polishing pad 3 and the heating fluid and cooling fluid, flowing in the heat exchanger 11, whereby the pad surface temperature is controlled.

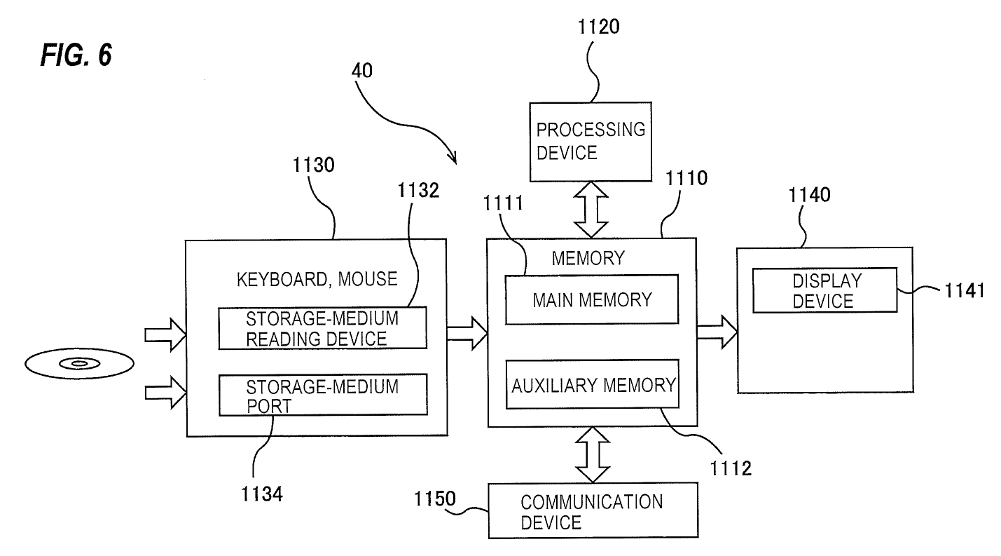

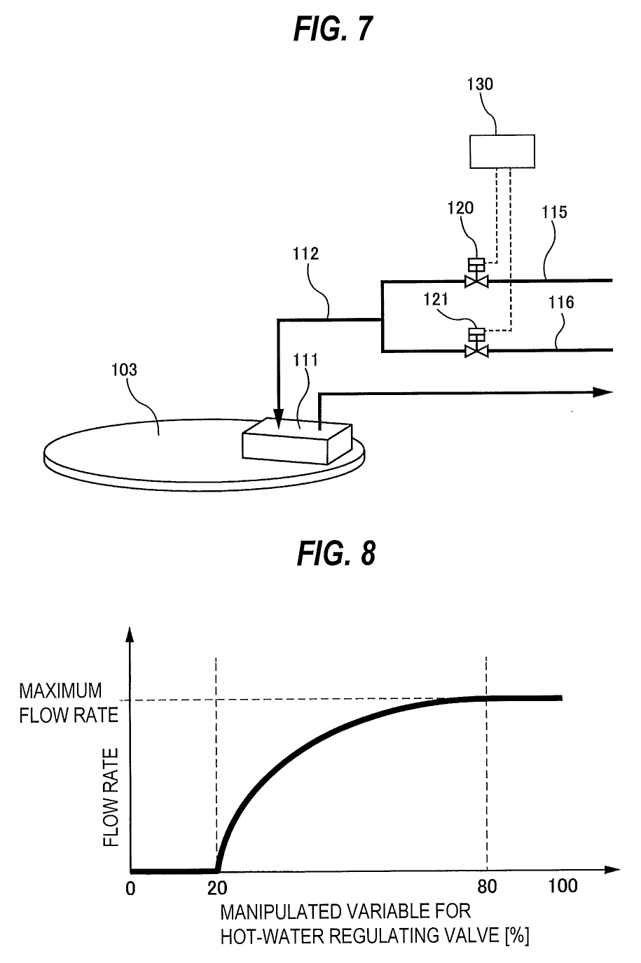

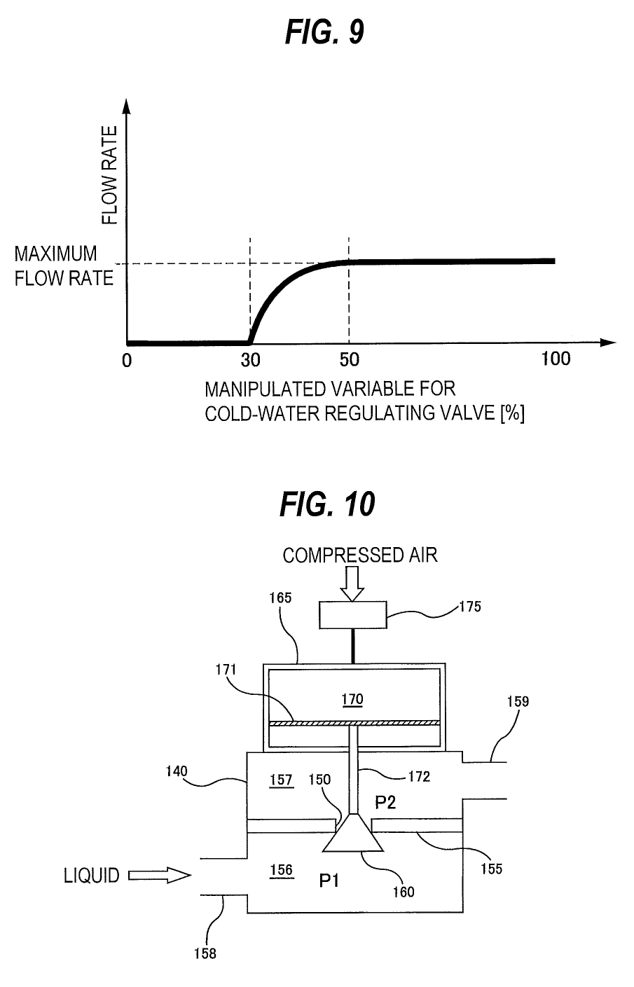

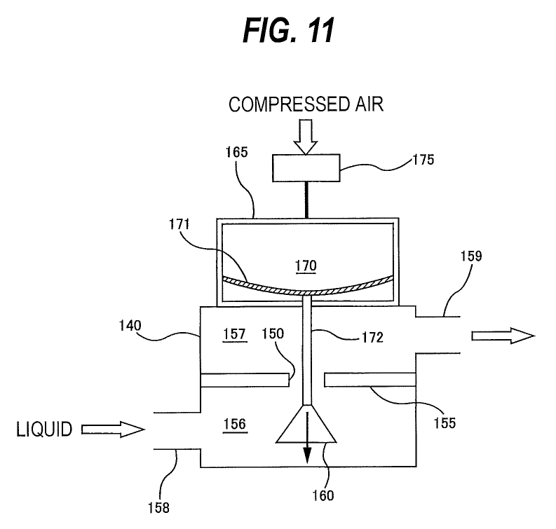

The valve controller 40 is constituted by a dedicated computer or a general-purpose computer. FIG. 6 is a schematic view showing an example of a structure of the valve controller 40. As shown in FIG. 6, the valve controller 40 includes a memory 1110 in which a program (including instructions) and data are stored, a processing device 1120, such as CPU (central processing unit), for performing arithmetic operation according to the program (or the instructions) stored in the memory 1110, an input device 1130 for inputting the data, the program, and various information into the memory 1110, an output device 1140 for outputting processing results and processed data, and a communication device 1150 for connecting to a network, such as the Internet.

The memory 1110 includes a main memory 1111 which is accessible by the processing device 1120, and an auxiliary memory 1112 that stores the data and the program therein. The main memory 1111 may be a random-access memory (RAM), and the auxiliary memory 1112 is a storage device which may be a hard disk drive (HDD) or a solid-state drive (SSD).

The input device 1130 includes a keyboard and a mouse, and further includes a storage-medium reading device 1132 for reading the data from a storage medium, and a storage-medium port 1134 to which a storage medium can be coupled. The storage medium is a non-transitory tangible computer-readable storage medium. Examples of the storage medium include optical disk (e.g., CD-ROM, DVD-ROM) and semiconductor memory (e.g., USB flash drive, memory card). Examples of the storage-medium reading device 1132 include optical drive (e.g., CD-ROM drive, DVD-ROM drive) and card reader. Examples of the storage-medium port 1134 include USB port. The program and/or the data stored in the storage medium is introduced into the valve controller 40 via the input device 1130, and is stored in the auxiliary memory 1112 of the memory 1110. The output device 1140 includes a display device 1141.

The valve controller 40 operates according to the program electrically stored in the memory 1110. Specifically, the valve controller 40 determines the heating-side manipulation range R1 by removing the dead bands L1, H1 of the first flow-rate control valve 42 from the range of manipulated variable for the first flow-rate control valve 42, sets a first manipulated variable, selected from the heating-side manipulation range R1, to the first flow-rate control valve 42 to cause the first flow-rate control valve 42 to operate according to the selected first manipulated variable, determines the cooling-side manipulation range R2 by removing the dead bands L2, H2 of the second flow-rate control valve 56 from the range of manipulated variable for the second flow-rate control valve 56, and sets a second manipulated variable, selected from the cooling-side manipulation range R2, to the second flow-rate control valve 56 to cause the second flow-rate control valve 56 to operate according to the selected second manipulated variable.

The program for causing the valve controller 40 to perform the above steps is stored in a non-transitory tangible computer-readable storage medium. The valve controller 40 is provided with the program via the storage medium. The valve controller 40 may be provided with the program via communication network, such as the Internet.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A method comprising:
determining a heating-side manipulation range by removing a dead band of a first flow-rate control valve from a range of manipulated variable for the first flow-rate control valve;
setting a first manipulated variable, selected from the heating-side manipulation range, to the first flow-rate control valve to cause the first flow-rate control valve to operate according to the selected first manipulated variable;
determines a cooling-side manipulation range by removing a dead band of a second flow-rate control valve from a range of manipulated variable for the second flow-rate control valve;
setting a second manipulated variable, selected from the cooling-side manipulation range, to the second flow-rate control valve to cause the second flow-rate control valve to operate according to the selected second manipulated variable; and
supplying a heating fluid that has passed through the first flow-rate control valve and a cooling fluid that has passed through the second flow-rate control valve to a heat exchanger disposed over a polishing pad to regulate a surface temperature of the polishing pad.

2. The method according to claim 1, wherein a sum of the first manipulated variable, selected from the heating-side manipulation range, and the second manipulated variable, selected from the cooling-side manipulation range, is 100% where each of the heating-side manipulation range and the cooling-side manipulation range is expressed as numerical values from 0% to 100%.

3. The method according to claim 1, wherein the dead band of the first flow-rate control valve includes a lower-side dead band located in a lower side of the range of manipulated variable for the first flow-rate control valve, and a higher-side dead band located in a higher side of the range of manipulated variable for the first flow-rate control valve.

4. The method according to claim 3, wherein:
a lower limit value of the heating-side manipulation range is equal to or larger than an upper limit value of the lower-side dead band of the first flow-rate control valve; and
an upper limit value of the heating-side manipulation range is equal to or smaller than a lower limit value of the higher-side dead band of the first flow-rate control valve.

5. The method according to claim 1, wherein the dead band of the second flow-rate control valve includes a lower-side dead band located in a lower side of the range of manipulated variable for the second flow-rate control valve, and a higher-side dead band located in a higher side of the range of manipulated variable for the second flow-rate control valve.

6. The method according to claim 5, wherein:
a lower limit value of the cooling-side manipulation range is equal to or larger than an upper limit value of the lower-side dead band of the second flow-rate control valve; and
an upper limit value of the cooling-side manipulation range is equal to or smaller than a lower limit value of the higher-side dead band of the second flow-rate control valve.

7. A polishing apparatus comprising:
a polishing table for supporting a polishing pad;
a polishing head configured to press a substrate against a surface of the polishing pad to polish the substrate;
an heat exchanger provided over the polishing pad;
a heating-fluid supply line and a cooling-fluid supply line coupled to the heat exchanger;
a first flow-rate control valve attached to the heating-fluid supply line;
a second flow-rate control valve attached to the cooling-fluid supply line; and
a valve controller coupled to the first flow-rate control valve and the second flow-rate control valve, the valve controller comprising instructions configured to:
determine a heating-side manipulation range by removing a dead band of the first flow-rate control valve from a range of manipulated variable for the first flow-rate control valve;
set a first manipulated variable, selected from the heating-side manipulation range, to the first flow-rate control valve to cause the first flow-rate control valve to operate according to the selected first manipulated variable;
determine a cooling-side manipulation range by removing a dead band of the second flow-rate control valve from a range of manipulated variable for the second flow-rate control valve; and
set a second manipulated variable, selected from the cooling-side manipulation range, to the second flow-rate control valve to cause the second flow-rate control valve to operate according to the selected second manipulated variable.

8. The polishing apparatus according to claim 7, wherein a sum of the first manipulated variable, selected from the heating-side manipulation range, and the second manipulated variable, selected from the cooling-side manipulation range, is 100% where each of the heating-side manipulation range and the cooling-side manipulation range is expressed as numerical values from 0% to 100%.

9. The polishing apparatus according to claim 7, wherein the dead band of the first flow-rate control valve includes a lower-side dead band located in a lower side of the range of manipulated variable for the first flow-rate control valve, and a higher-side dead band located in a higher side of the range of manipulated variable for the first flow-rate control valve.

10. The polishing apparatus according to claim 9, wherein:
a lower limit value of the heating-side manipulation range is equal to or larger than an upper limit value of the lower-side dead band of the first flow-rate control valve; and
an upper limit value of the heating-side manipulation range is equal to or smaller than a lower limit value of the higher-side dead band of the first flow-rate control valve.

11. The polishing apparatus according to claim 7, wherein the dead band of the second flow-rate control valve includes a lower-side dead band located in a lower side of the range of manipulated variable for the second flow-rate control valve, and a higher-side dead band located in a higher side of the range of manipulated variable for the second flow-rate control valve.

12. The polishing apparatus according to claim 11, wherein:
a lower limit value of the cooling-side manipulation range is equal to or larger than an upper limit value of the lower-side dead band of the second flow-rate control valve; and
an upper limit value of the cooling-side manipulation range is equal to or smaller than a lower limit value of the higher-side dead band of the second flow-rate control valve.
